(19) United States
(12) Patent Application Publication
(10) Pub. No.: US 2014/0138809 A1
(43) Pub. Date: May 22, 2014

(54) PACKAGE STRUCTURE AND MANUFACTURING METHOD THEREOF

(71) Applicant: Raydium Semiconductor Corporation, Hsinchu (TW)

(72) Inventors: Chia-Hung Hsu, New Taipei City (TW); Ching-Yung Chen, Taoyuan County (TW)

(21) Appl. No.: 14/082,626

(22) Filed: Nov. 18, 2013

(30) Foreign Application Priority Data
Nov. 20, 2012 (TW) 101143287

(51) Int. Cl. H01L 23/495; H01L 21/48

(52) U.S. Cl. CPC H01L 23/49575; H01L 21/4821
USPC 257/668; 438/123

(57) ABSTRACT

A package structure and a manufacturing method thereof are disclosed. The package structure includes an outer lead, a driver chip, a soft material, and a solidified material. There is a distance between the driver chip and the outer lead. The soft material is used to fill the space in the package structure except the driver chip and the outer lead. The solidified material is formed in at least one region on the soft material between the driver chip and the outer lead. The hardness of the solidified material is higher than the hardness of the soft material.

### BACKGROUND OF THE INVENTION

1. Field of the Invention

The invention relates to a driving IC of a display; in particular, to a package structure and a manufacturing method thereof capable of effectively reducing the thermal expansion amount and preventing the fracture by stress.

2. Description of the Related Art

In general, current package processes used to package a driving IC of a display includes:
(1) a tape carrier package (TCP) process,
(2) a chip on film (COF) package process, and
(3) a chip on glass (COG) package process.

The TCP process and the COF package process are widely used in driving IC package and test factories. Since the COF package structure is flexible, it is more flexible than the TCP process. No matter TCP process or the COF package process is used, it is necessary to be baked in the oven for a long time after the glue is coated to make the glue completely dehumidified and become a solidified material.

However, with the increasing of the pin number of the driving IC of the liquid crystal display from 384, 480 to 1440, 1920, it is more difficult to use the outer lead bonding (OLB) process in COF package process, especially the yield of the OLB process will become poor due to the thermal expansion variance of the OLB process.

Based on practical applications, it can be found that if the expansion of the OLB process is larger, the expansion variance of the OLB process will also become larger. Therefore, if the expansion of the OLB process can be reduced, it is helpful to reduce the expansion variance of the OLB process. However, the expansion of the OLB process is related to a distance between the driving IC and the OLB region, and this distance is hard to change and limited by the mechanical design of the display panel, therefore, when the COF package process is used, the expansion variance of the OLB process cannot be reduced by a way of reducing the expansion of the OLB process, so that the poor yield of the OLB process cannot be improved.

Therefore, the invention provides a package structure and manufacturing method thereof to solve the above-mentioned problems occurred in the prior arts.

### SUMMARY OF THE INVENTION

An embodiment of the invention is a package structure. In this embodiment, the package structure includes an outer lead, a driver chip, a soft material, and a solidified material. There is a distance between the driver chip and the outer lead. The soft material is used to fill the space in the package structure except the driver chip and the outer lead. The solidified material is formed in at least one region on the soft material between the driver chip and the outer lead. The hardness of the solidified material is higher than the hardness of the soft material.

In an embodiment, the driver chip is applied in a liquid crystal display.

In an embodiment, the package structure is manufactured by a chip on film (COF) packaging process.

In an embodiment, an underfill is formed in the at least one region on the soft material between the driver chip and the outer lead and completely dehumidified after baking to become the solidified material.

In an embodiment, the underfill is formed in the at least one region on the soft material between the driver chip and the outer lead by a coating way or an attaching way.

Another embodiment of the invention is a method of manufacturing a package structure. In this embodiment, the method includes steps of: (a) providing a driver chip and an outer lead, wherein a distance is existed between the driver chip and the outer lead; (b) filling a soft material into a space in the package structure except the driver chip and the outer lead; (c) forming an underfill in the at least one region on the soft material between the driver chip and the outer lead; and (d) curing the underfill by heat to form a solidified material in the at least one region, wherein the hardness of the solidified material is higher than the hardness of the soft material.

Compared to the prior art, the package structure and the manufacturing method thereof according to the invention use the feature that the underfill used in the driving IC package process can be solidified by heat to coat the underfill near the OLB region in the OLB process, and at least one region between the driving IC and the outer lead will be solidified by heat; therefore, the thermal expansion degree of the COF package process can be limited to reduce the expansion variance and improve the yield of the COF package process and the folding capability of the bending stress region between the driving chip and the outer lead.

The advantage and spirit of the invention may be understood by the following detailed descriptions together with the appended drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic diagram of the package structure in an embodiment of the invention.

FIG. 2 illustrates a schematic diagram of the package structure in another embodiment of the invention.

FIG. 3 illustrates a schematic diagram of the package structure in another embodiment of the invention.

FIG. 4 illustrates a flow chart of the package structure manufacturing method in another embodiment of the invention.

### DETAILED DESCRIPTION

An embodiment of the invention is a package structure. In this embodiment, the package structure is a driving IC package structure in the liquid crystal display and manufactured by a chip on film (COF) package process, but not limited to this.

Please refer to FIG. 1. FIG. 1 illustrates a schematic diagram of the package structure in an embodiment of the invention. As shown in FIG. 1, the package structure 1 includes an outer lead 10, a driver chip 12, a soft material 14, and a solidified material 16. The soft material 14 is used to fill the space in the package structure 1 except the driver chip 12 and the outer lead 10. The solidified material 16 is formed in a region R on the soft material 14 between the driver chip 12 and the outer lead 10. In fact, a distance between the driver chip 12 and the outer lead 10 and the number, shape, size of the region R can be determined based on practical needs without any specific limitations.

It should be noticed that the an underfill usually used in driving IC package process is coated or attached in the region R on the soft material 14 between the driver chip 12 and the outer lead 10 and then completely dehumidified after baking to become the solidified material 16. The hardness of the solidified material 16 is higher than the hardness of the soft material 14.

In the prior art, the soft material having poor hardness is filled between the driving chip and the outer lead, it fails to reduce the thermal expansion degree of the OLB process; therefore, the expansion variance of the OLB process cannot be reduced and the yield of the package structure cannot be improved, and the folding capability of the bending stress region between the driving chip and the outer lead is also poor.

Different from the prior art, the feature that the underfill used in the driving IC package process can be solidified by heat is used in this embodiment, in the COF package process, the underfill is coated in the region R on the soft material 14 between the driver chip 12 and the outer lead 10, namely near the OLB region, therefore, the underfill in the region R on the soft material 14 between the driver chip 12 and the outer lead 10 will be solidified by heat to limit the thermal expansion degree of the OLB process and reduce the expansion variance of the OLB process, and the yield of the package structure 1 can be improved and the folding capability of the bending stress region between the driving chip 12 and the outer lead 10 can be also enhanced. Even the number of the pins of the driving IC of the liquid crystal display is increasing the aligning accuracy of the OLB process will not become poor.

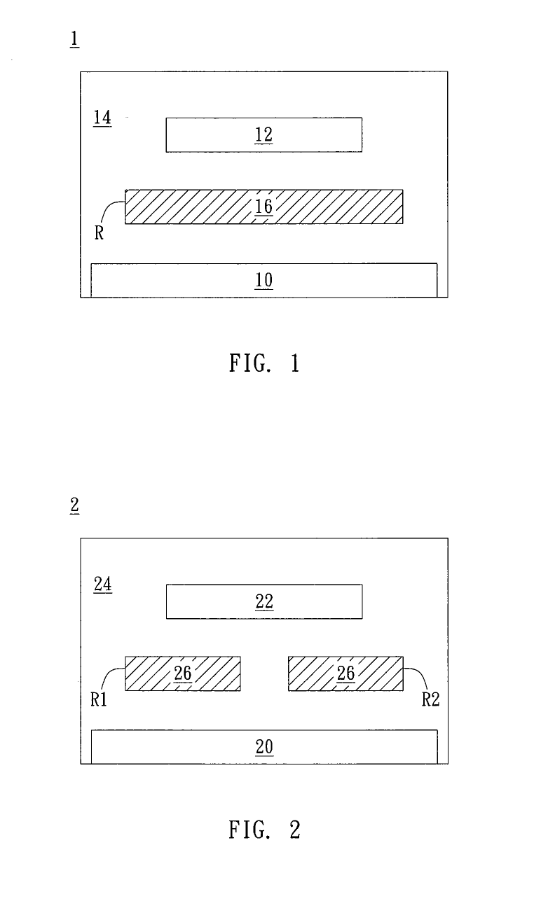

Please refer to FIG. 2. FIG. 2 illustrates a schematic diagram of the package structure in another embodiment of the invention. As shown in FIG. 2, the package structure 2 includes an outer lead 20, a driver chip 22, a soft material 24, and a solidified material 26. The soft material 24 is used to fill the space in the package structure 2 except the driver chip 22 and the outer lead 20. The solidified material 26 is formed in a first region R1 and a second region R2 on the soft material 24 between the driver chip 22 and the outer lead 20. It should be noticed that the first region R1 and the second region R2 of this embodiment are located at the right side and the left side between the driver chip 22 and the outer lead 20, but not limited to this.

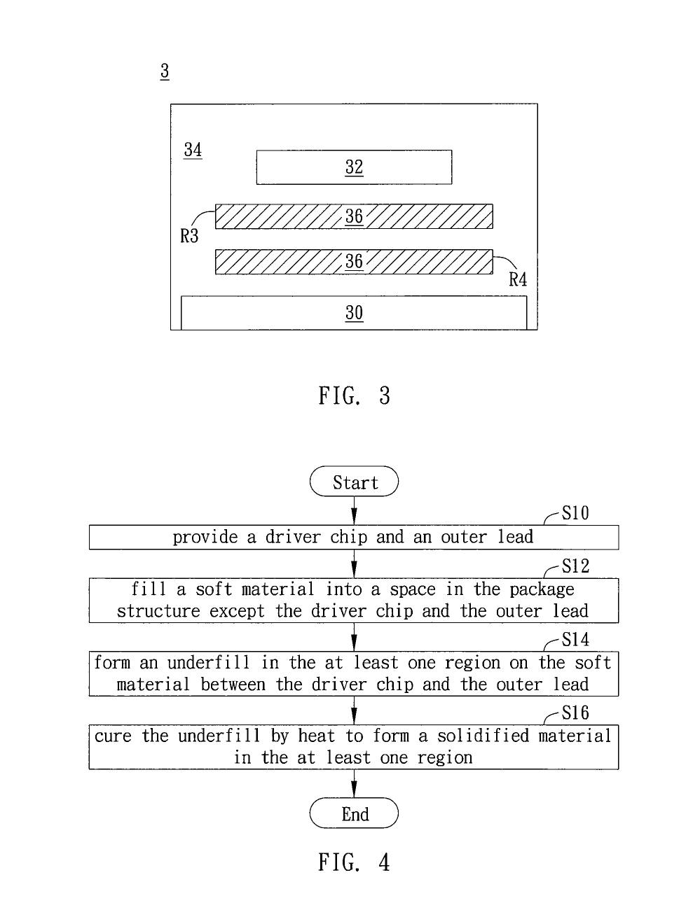

Please refer to FIG. 3. FIG. 3 illustrates a schematic diagram of the package structure in another embodiment of the invention. As shown in FIG. 3, the package structure 3 includes an outer lead 30, a driver chip 32, a soft material 34, and a solidified material 36. The soft material 34 is used to fill the space in the package structure 3 except the driver chip 32 and the outer lead 30. The solidified material 36 is formed in a third region R3 and a fourth region R4 on the soft material 34 between the driver chip 32 and the outer lead 30. It should be noticed that the third region R3 and the fourth region R4 of this embodiment are both located between the driver chip 32 and the outer lead 30, wherein the third region R3 is closer to the driver chip 32 and the fourth region R4 is closer to the outer lead 30, but not limited to this.

As mentioned above, the number, shape, and size of the regions of the solidified material formed between the driver chip and the outer lead are determined based on practical needs without any specific limitations.

Another embodiment of the invention is a method of manufacturing a package structure. In this embodiment, the method uses a chip on film (COF) package process to manufacture a driving IC package structure in the liquid crystal display, but not limited to this.

Please refer to FIG. 4. FIG. 4 illustrates a flow chart of the package structure manufacturing method in this embodiment. As shown in FIG. 4, in the step S10, the method provides a driver chip and an outer lead. A distance is existed between the driver chip and the outer lead. In the step S12, the method fills a soft material into a space in the package structure except the driver chip and the outer lead. In the step S14, the method forms an underfill in the at least one region on the soft material between the driver chip and the outer lead. In the step S16, the method cures the underfill by heat to form a solidified material in the at least one region, wherein the hardness of the solidified material is higher than the hardness of the soft material.

Compared to the prior art, the package structure and the manufacturing method thereof according to the invention use the feature that the underfill used in the driving IC package process can be solidified by heat to coat the underfill near the OLB region in the OLB process, and at least one region between the driving IC and the outer lead will be solidified by heat; therefore, the thermal expansion degree of the COF package process can be limited to reduce the expansion variance and improve the yield of the COF package process and the folding capability of the bending stress region between the driving chip and the outer lead.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. A package structure, comprising:
an outer lead;
a driver chip, wherein a distance is existed between the driver chip and the outer lead;
a soft material, for filling a space in the package structure except the driver chip and the outer lead; and
a solidified material, formed in at least one region on the soft material between the driver chip and the outer lead, wherein the hardness of the solidified material is higher than the hardness of the soft material.

2. The package structure of claim 1, wherein the driver chip is applied in a liquid crystal display.

3. The package structure of claim 1, wherein the package structure is manufactured by a chip on film (COF) packaging process.

4. The package structure of claim 1, wherein an underfill is formed in the at least one region on the soft material between the driver chip and the outer lead and completely dehumidified after baking to become the solidified material.

5. The package structure of claim 4, wherein the underfill is formed in the at least one region on the soft material between the driver chip and the outer lead by a coating way or an attaching way.

6. A method of manufacturing a package structure, the method comprising steps of:
(a) providing a driver chip and an outer lead, wherein a distance is existed between the driver chip and the outer lead;
(b) filling a soft material into a space in the package structure except the driver chip and the outer lead;
(c) forming an underfill in the at least one region on the soft material between the driver chip and the outer lead; and
(d) curing the underfill by heat to form a solidified material in the at least one region, wherein the hardness of the solidified material is higher than the hardness of the soft material.

7. The method of claim 6, wherein the driver chip is applied in a liquid crystal display.

8. The method of claim 6, wherein the package structure is manufactured by a chip on film (COF) packaging process.

9. The method of claim 6, wherein in the step (c), the underfill is formed in the at least one region on the soft material between the driver chip and the outer lead by a coating way or an attaching way.
